(19) United States
(12) Patent Application Publication
(10) Pub. No.: US 2019/0335619 A1
(43) Pub. Date: Oct. 31, 2019

(54) LOOP HEAT TRANSFER DEVICE WITH GASEOUS AND LIQUID WORKING FLUID CHANNELS SEPARATED BY PARTITION WALL

(71) Applicant: TAI-SOL ELECTRONICS CO., LTD., TAIPEI CITY (TW)

(72) Inventors: Chuan-Chi TSENG, TAIPEI CITY (TW); Wen-Ching LIAO, TAIPEI CITY (TW); Ming-Quan CUI, WUJIANG CITY (CN)

(21) Appl. No.: 16/050,390

(22) Filed: Jul. 31, 2018

(30) Foreign Application Priority Data
Apr. 26, 2018 (TW) 107114330

(51) Int. Cl. H05K 7/20; F28D 15/02; F28D 15/04; F28D 9/00; F28F 3/12

(52) U.S. Cl. CPC H05K 7/20336; F28D 15/0266; F28D 15/0275; F28F 2240/00; F28D 9/0062; F28F 3/12; F28D 15/046

(57) ABSTRACT

A loop heat transfer device has therein an enclosed space being vacuum and filled with a working fluid. The loop heat transfer device includes a base, a partition wall, an upper lid, and a capillarity structure. The base includes a first chamber, a second chamber and an extension groove. The extension groove extends from the first chamber to the second chamber. The partition wall connects to the base and partitions the extension groove into a capillarity channel and an airstream channel. The upper lid connects to the base and the partition wall. The enclosed space includes the first chamber, the second chamber and the extension groove. The capillarity structure is disposed in the first chamber, the second chamber and the capillarity channel.

### BACKGROUND OF THE INVENTION

### 1. Technical Field

The present disclosure relates to heat transfer devices and, more particularly, to a loop heat transfer device.

### 2. Description of Related Art

US 2016/0128234A1 discloses a cooling device and an electronic apparatus. The cooling device essentially comprises two plates, namely a heat receiving plate and a heat radiation plate, an air tube, and a liquid tube. The air tube and the liquid tube together connect the heat receiving plate and the heat radiation plate to form a loop vapor chamber conducive to separation of liquid and gas.

The heat receiving plate, the heat radiation plate, the air tube, and the liquid tube are usually connected by a welding process in order to form the loop vapor chamber.

However, the welding process not only destroys the metallic structure of the plates (for example, carbonizing the metal at the welding point) but also increases the chance that the plates will get damaged because of a collision during a subsequent process or delivery or because of long use.

Furthermore, the loop vapor chamber made by the welding process is usually huge. Such a huge heat-dissipating apparatus is inapplicable to light, thin electronic products. Therefore, it is important to not only effectively reduce the volume of the loop vapor chamber but also enable gaseous and liquid working fluids to flow smoothly and efficiently within the loop vapor chamber.

### BRIEF SUMMARY OF THE INVENTION

In view of the aforesaid drawbacks of the prior art, it is an objective of the present disclosure to provide a loop heat transfer device with adjacent, separate extending channels such that a working fluid flows efficiently, so as to reduce the volume of the loop heat transfer device and extend its service life, but the aforesaid technical features are not restrictive of the advantages of the present disclosure.

In order to achieve the above and other objectives, the present disclosure provides a loop heat transfer device having therein an enclosed space being vacuum and filled with a working fluid. The loop heat transfer device comprises a base, a partition wall, an upper lid, and a capillarity structure. The base comprises a first chamber, a second chamber and an extension groove. The extension groove extends from the first chamber to the second chamber. The extension groove has a first end and a second end. The first end of the extension groove corresponds in position to the first chamber. The second end of the extension groove corresponds in position to the second chamber. The partition wall connects to the base and extends from the first end of the extension groove to the second end of the extension groove so as to partition the extension groove into a capillarity channel and an airstream channel. The capillarity channel and the airstream channel connect to the first chamber and the second chamber communicatively. The upper lid connects to the base and the partition wall. The enclosed space comprises the first chamber, the second chamber and the extension groove. The capillarity structure is disposed in the first chamber, the second chamber, and the capillarity channel of the extension groove.

A gaseous working fluid moves between the first chamber and the second chamber through the airstream channel to transfer heat to a cooler chamber. Then, the gaseous working fluid in the capillarity structure in the cooler chamber turns into a liquid working fluid; hence, temperate at the surface of the base and the surface of the upper lid is substantially uniform.

Since the loop heat transfer device of the present disclosure partitions a single chamber into airstream and capillarity channels, the loop heat transfer device of the present disclosure surpasses conventional loop heat transfer devices in structure and volume reduction, thereby being applicable to light, thin electronic products.

Fine structures, features, assembly or ways of use of the loop heat transfer device of the present disclosure are described in detail below with reference to preferred embodiments. However, persons skilled in the art understand that the detailed descriptions and specific embodiments put forth to describe the embodiment of the present disclosure are illustrative of the present disclosure rather than restrictive of the claims of the present disclosure.

### BRIEF DESCRIPTION OF THE SEVERAL VIEWS OF THE DRAWINGS

FIG. 1 is an exploded view of a loop heat transfer device according to an embodiment of the present disclosure;

FIG. 2 is a partial exploded view of the loop heat transfer device according to an embodiment of the present disclosure;

FIG. 3 is a perspective schematic view of the loop heat transfer device which is assembled and shown in FIG. 2 according to an embodiment of the present disclosure;

FIG. 4 is a cross-sectional view of the loop heat transfer device taken along line A-A of FIG. 3 according to an embodiment of the present disclosure;

FIGS. 5-7 is an exploded view of the loop heat transfer device with two extension grooves and two partition walls according to an embodiment of the present disclosure;

FIG. 8 is an exploded view of the loop heat transfer device with three extension grooves and three partition walls according to an embodiment of the present disclosure;

FIG. 9 is an exploded view of the loop heat transfer device with the extension grooves, a capillarity groove and an airstream groove according to an embodiment of the present disclosure;

FIG. 10 is a partial exploded view of the loop heat transfer device of FIG. 9 according to an embodiment of the present disclosure; and

FIG. 11 is an exploded view of the loop heat transfer device according to an embodiment of the present disclosure, showing that it has less capillarity structure than is shown in FIG. 2.

### DETAILED DESCRIPTION OF THE INVENTION

Constituent elements and achievable advantages of a loop heat transfer device of the present disclosure are hereunder illustrated by drawings and preferred embodiments. However, elements, dimensions and appearance of the loop heat transfer device, as shown in the drawings, are illustrative of the technical features of the present disclosure rather than restrictive of the present disclosure.

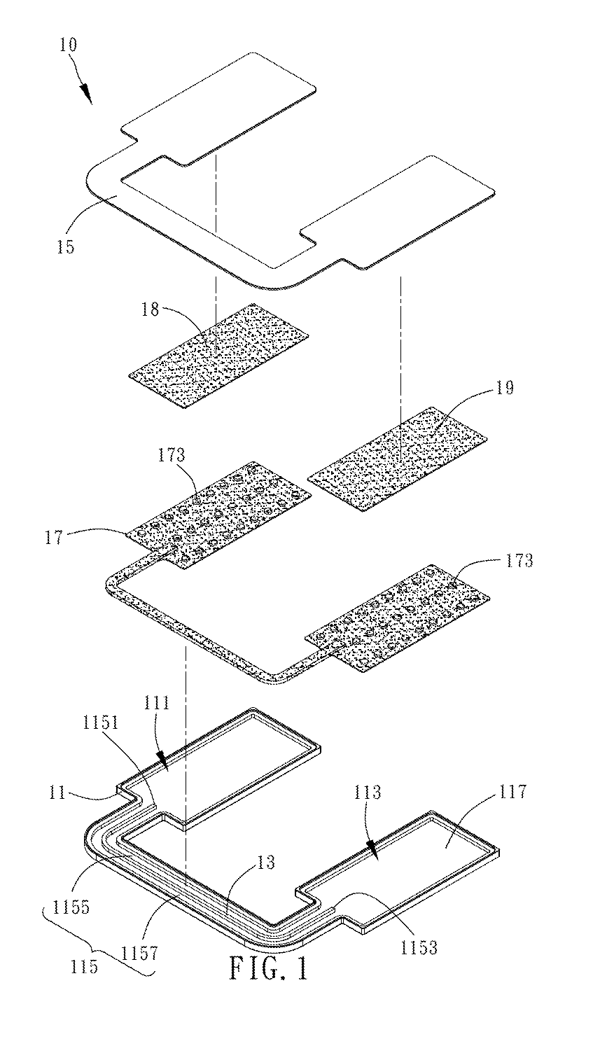

Referring to FIGS. 1-4, there are shown exploded views, a perspective view and a cross-sectional view of a loop heat transfer device according to an embodiment of the present disclosure. The loop heat transfer device 10 of the present disclosure comprises a base 11, a partition wall 13, an upper lid 15, and a capillarity structure. In this embodiment, the capillarity structure comprises a first capillarity layer 17, a second capillarity layer 18 and a third capillarity layer 19. However, in another embodiment, the capillarity structure can have less or more layers, and their arrangement within an enclosed space is not restricted to the disclosure of this embodiment. The base 11 comprises a first chamber 111, a second chamber 113 and an extension groove 115. The extension groove 115 extends from the first chamber 111 to the second chamber 113, connects the first chamber 111 and the second chamber 113 communicatively, and has a first end 1151 and a second end 1153. The first end 1151 corresponds in position to the first chamber 111, defining a junction between the extension groove 115 and the first chamber 111. The second end 1153 corresponds in position to the second chamber 113, defining a junction between the extension groove 115 and the second chamber 113.

A bottom surface 117 of the first chamber 111, a bottom surface 117 of the second chamber 113, and a bottom surface 117 of the extension groove 115 located on the same horizontal plane. In another embodiment, the first chamber 111, the second chamber 113, and a chamber bottom 117 of the extension groove 115 lie in different horizontal planes or some in the same horizontal plane but some in different horizontal planes. In another embodiment, the first chamber 111, the second chamber 113, and a bottom of the extension groove 115 lie in different horizontal planes.

The partition wall 13 connects to the base 11, lies in the extension groove 115, and extends from the first end 1151 of the extension groove 115 to the second end 1153 of the extension groove 115, so as to partition the extension groove 115 into two separate channels 1155, 1157, namely a capillarity channel 1155 and an airstream channel 1157. In this embodiment, the partition wall 13 extends upward from the base 11 to form an integrally formed structure. However, in another embodiment, the partition wall 13 and the base 11 are separate elements connected by a means of connection.

The capillarity channel 1155 and the airstream channel 1157 occupy the space of the extension groove 115 equally; hence, the capillarity channel 1155 and the airstream channel 1157 take up the same amount of space in the extension groove 115. In another embodiment, the capillarity channel 1155 and the airstream channel 1157 occupy the space of the extension groove 115 unequally; for example, the capillarity channel 1155 takes up less space than the airstream channel 1157, or the capillarity channel 1155 takes up more space than the airstream channel 1157.

In another embodiment, much more channels, for example, several capillarity channels 1155 and several airstream channels 1157, are formed within the extension groove 115. Although the present disclosure discloses a capillarity channel 1155 and an airstream channel 1157, they are not restrictive in terms of quantity; hence, they not only apply to any other embodiments in which the extension groove 115 has therein much more capillarity channels 1155 and airstream channels 1157, but also apply to any other embodiments in which the capillarity channels 1155 equal or do not equal the airstream channels 1157 in quantity. Therefore, the partition walls increase with the channels within the extension groove 115.

The upper lid 15 connects to the base 11 and the partition wall 13 such that the first chamber 111, the second chamber 113 and the extension groove 115 together form an enclosed space. The enclosed space is vacuum and filled with a working fluid (such as water) such that the working fluid can turn into a gaseous or liquid working fluid within the enclosed space. The gaseous or liquid working fluid circulates and thus effects heat dissipation.

The upper lid 15 matches the base 11 substantially in profile. However, in another embodiment, the upper lid 15 and the base 11 need not match in profile in a top view on condition that the enclosed space can be formed.

In this embodiment, the base 11 and the upper lid 15 each form an integrally formed structure by CNC or a means of etching. In another embodiment, the integrally formed structures are formed by another means of processing or formed by two different means of processing, respectively.

The first capillarity layer 17, the second capillarity layer 18, and the third capillarity layer 19 are each formed within the enclosed space. The first capillarity layer 17 is formed at the base 11 and disposed in the first chamber 111, the second chamber 113 and the capillarity channels 1155. The second capillarity layer 18 is formed at the upper lid 15 and faces the first chamber 111. The third capillarity layer 19 is formed at the upper lid 15 and faces the second chamber 113.

The first capillarity layer 17, the second capillarity layer 18, and the third capillarity layer 19 consists of metal particles, metallic netting, metallic fibers, metallic wires, or grooves. The first, second and third capillarity layers 17, 18, 19 are connected to the base 11, the partition wall 13 and the upper lid 15 by sintering; the sintering process produces capillary pores penetrable by the working fluid. When provided in the form of the grooves, the first, second and third capillarity layers 17, 18, 19 are formed by scratching the surface of the upper lid 15.

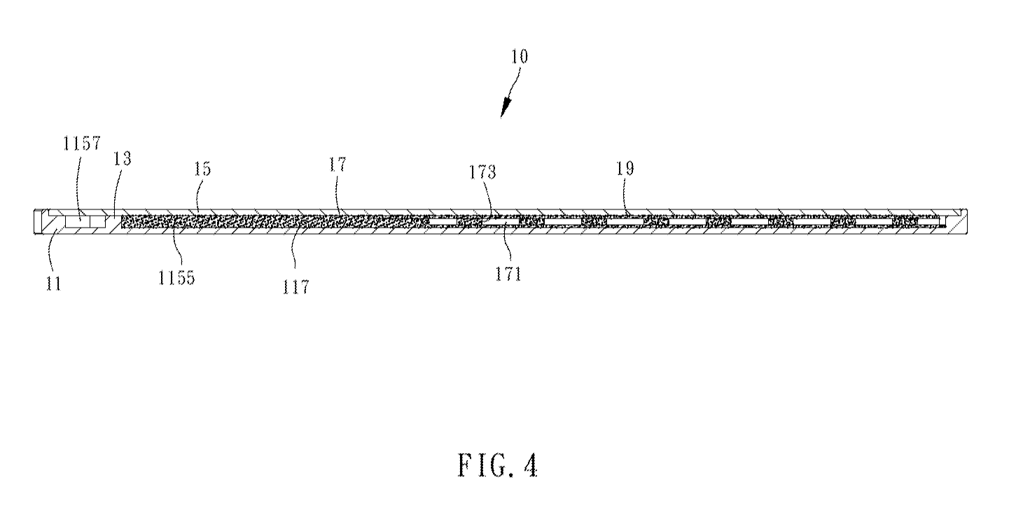

A hollow-core cavity 171 is disposed not only between the first capillarity layer 17 and the second capillarity layer 18 but also between the first capillarity layer 17 and the third capillarity layer 19, as shown in FIG. 4. The two hollow-core cavities 171 have different structures but the same function, and their function is to facilitate the flow of a gaseous working fluid. The hollow-core cavities 171 connect the airstream channels 1157 communicatively so as to allow the gaseous working fluid to flow within the enclosed space.

The first capillarity layer 17 has support portions 173. The support portions 173 are spaced apart and disposed in the hollow-core cavities 171 to support the base 11 and the upper lid 15. The support portions 173 are supportive structures which have shapes of cylinders, cones, bars or another geometric shapes. The support portions 173 either have capillary pores or do not have any capillary pores, and thus their structures are not limited by the accompanying drawings. The main purpose of the support portions 173 is to support the base 11 and the upper lid 15. Therefore, distances between adjacent ones of the support portions 173 and the arrangements of the support portions 173 are not limited by this embodiment. However, persons skilled in the art know very well that the aforesaid distances are much greater than diameters of the capillary pores of the first capillarity layer 17 and are well aware of the diameters of the capillary pores of the first capillarity layer 17.

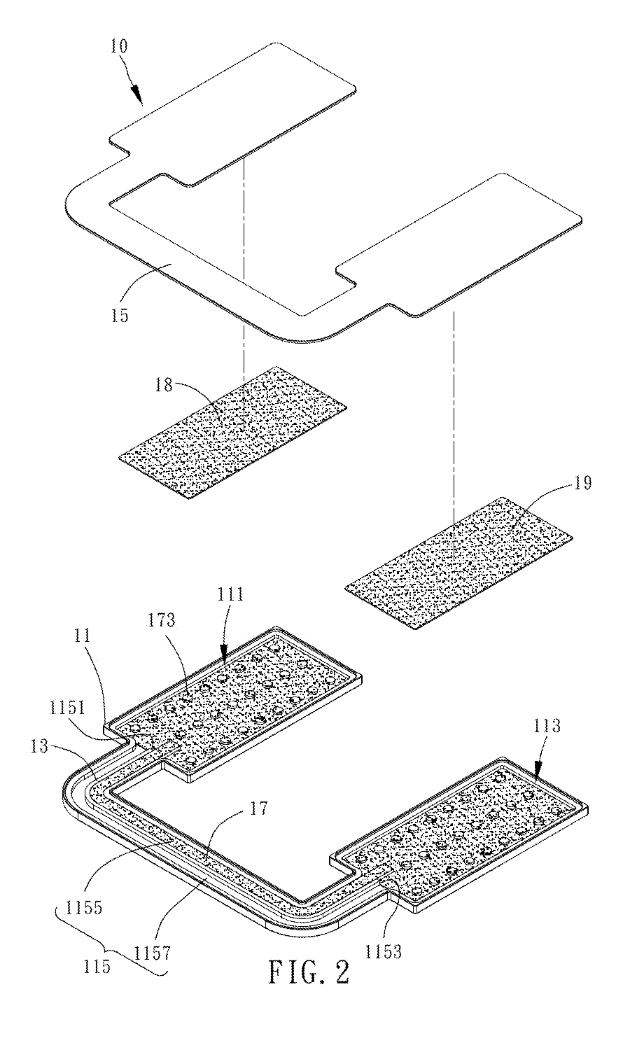

In this embodiment, as shown in FIGS. 1 and 2, the first capillarity layer 17 connects to the base 11, whereas the second capillarity layer 18 and the third capillarity layer 19 each connect to the upper lid 15. In another embodiment, the first capillarity layer 17, second capillarity layer 18 and third capillarity layer 19 together form a multilayer structure with less layers/levels or more layers/levels, for example, a monolayer structure or a single-level structure, or a structure with two or more layers. The support portions 173 are formed on each of the first, second and third capillarity layers 17, 18, 19. Alternatively, the first, second and third capillarity layers 17, 18, 19 form their respective support portions 173.

The base 11 and the upper lid 15 of the loop heat transfer device 10 of the present disclosure are also made of metal and tightly coupled together by a means of heating or any other means of coupling so as to form the enclosed space.

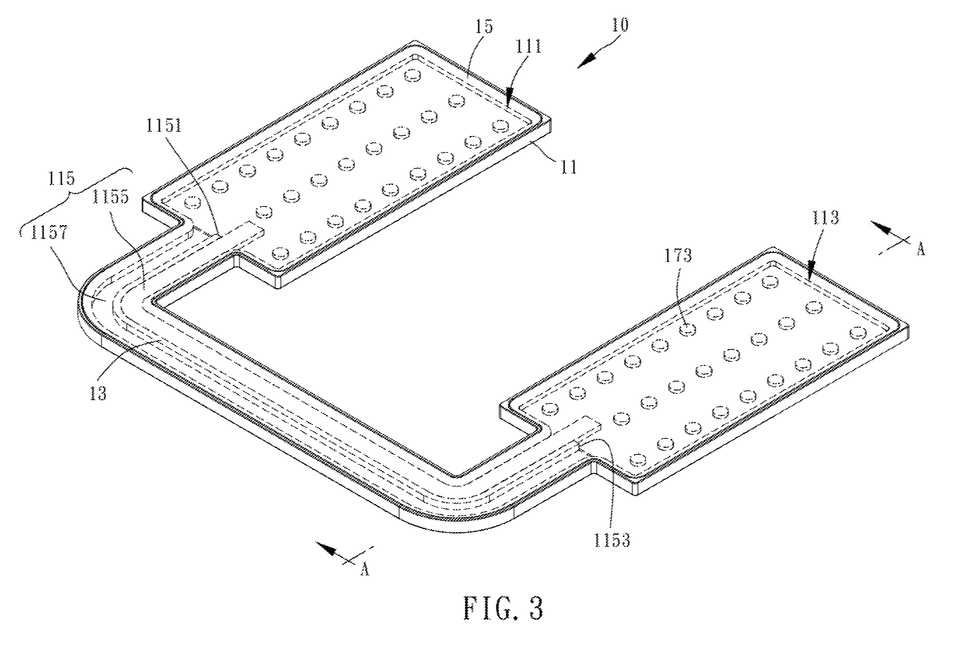

Referring to FIG. 3, according to the present disclosure, the loop heat transfer device 10 in operation uses a corresponding surface of the first chamber 111 as a heat-receiving region. The heat-receiving region is adapted to come into contact with a heat source and receive heat from the heat source. The heat source is a microprocessor, an integrated circuit, an RF component, or any other component or module capable of generating heat. The module is an electronic circuit which comprises one or more aforesaid components and another electronic component.

A corresponding surface of the second chamber 113 functions as a heat-dissipating region. The heat-dissipating region is in direct or indirect contact with a heat-dissipating module. In the event of direct contact, the heat-dissipating module is in direct contact with the heat-dissipating region by a cooling fin assembly or a combination of a fan and a cooling fin assembly in order to cool the heat-dissipating region. In the event of indirect contact, the heat-dissipating module is not in contact with the heat-dissipating region but cools the heat-dissipating region through a fluid. The fluid is, for example, an air current generated by a fan. In another embodiment, the heat-dissipating module uses a plurality of cooling fin assemblies, a plurality of fans, or another component, and thus the constituents of the heat-dissipating module are not limited thereto.

After the heat-receiving region has received heat, the liquid working fluid in the first capillarity layer 17 of the first chamber 111 corresponding in position to the heat-receiving region turns into a gaseous working fluid. The gaseous working fluid goes through the airstream channels 1157 and reaches the first capillarity layer 17 of the second chamber 113 corresponding in position to the heat-dissipating region, so as to come into contact with the first capillarity layer 17 corresponding in position to the heat-dissipating region. As a result, the gaseous working fluid condenses and turns into a liquid working fluid. The liquid working fluid enters the first capillarity layer 17 and flows past the second chamber 113, the capillarity channels 1155 and the first chamber 111 sequentially to implement a circulation path for converting the liquid and gaseous working fluids into each other, so as for the loop heat transfer device to effect heat dissipation.

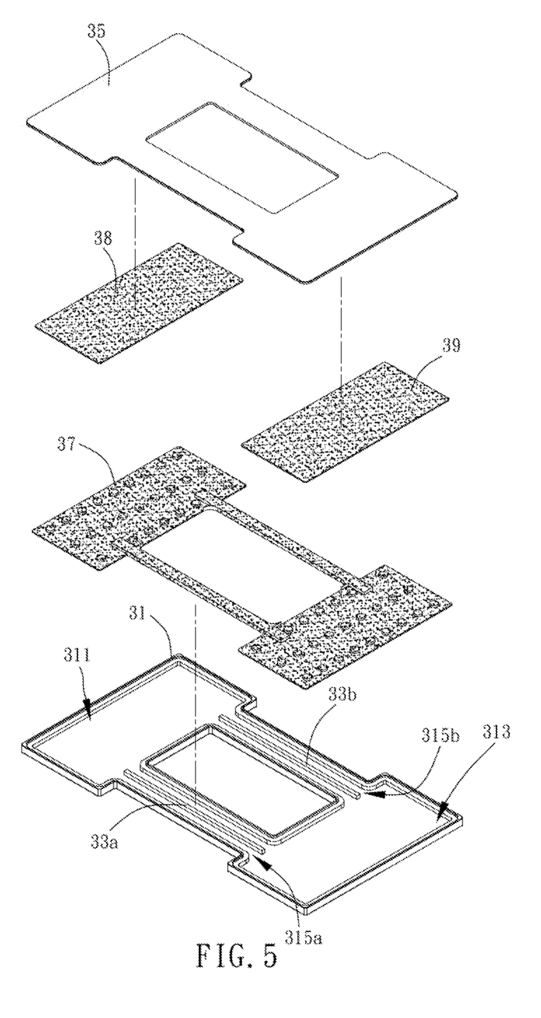

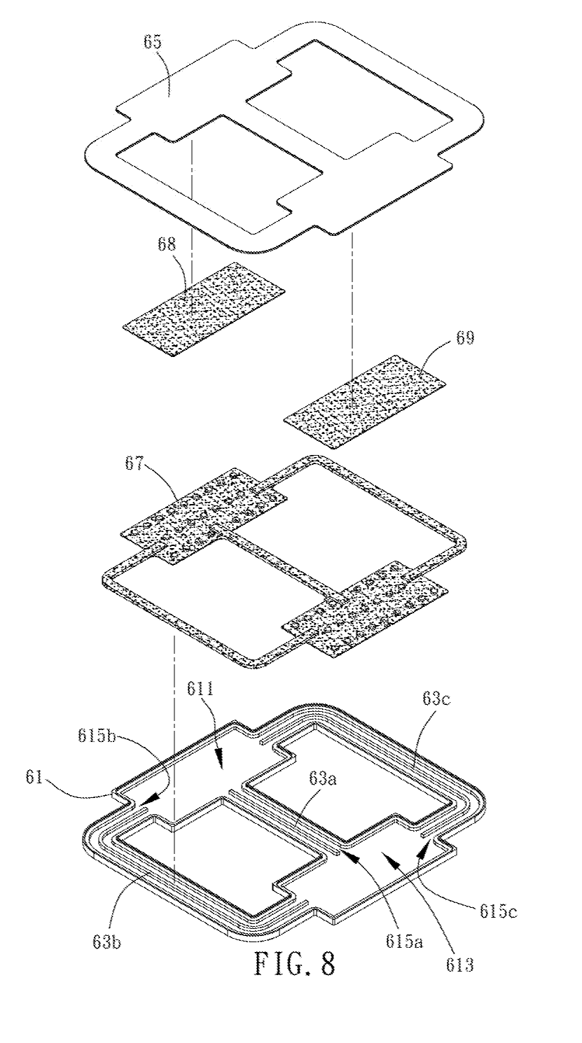

In another embodiment, the quantity of the extension groove 115 of the base 11 and the partition wall 13 can increase to, for example, two, three or more. Since exploded views depict technical features of any embodiment best, it is advantageous for FIGS. 5-8 to show exploded views of the loop heat transfer device according to another embodiment of the present disclosure, for FIGS. 5-7 to show exploded views of the loop heat transfer device having two extension grooves according to yet another embodiment of the present disclosure, and for FIG. 8 to show an exploded view of the loop heat transfer device having three extension grooves according to still yet another embodiment of the present disclosure.

Referring to FIG. 5, an upper lid 35, a base 31, a first capillarity layer 37, a second capillarity layer 38 and a third capillarity layer 39 are formed in the same manner, connected by the same means, and intended to serve the same purposes as their aforesaid counterparts shown in FIG. 1 and thus, for the sake of brevity, are not described below. However, FIG. 5 is distinguished from FIG. 1 by technical features described below. Referring to FIG. 5, extension grooves 315a, 315b extend in a unique manner. In this embodiment, the two extension grooves 315a, 315b run parallel to each other and extend from a first chamber 311 toward a second chamber 313, whereas two partition walls 33a, 33b extend in the same direction as the two extension grooves 315a, 315b.

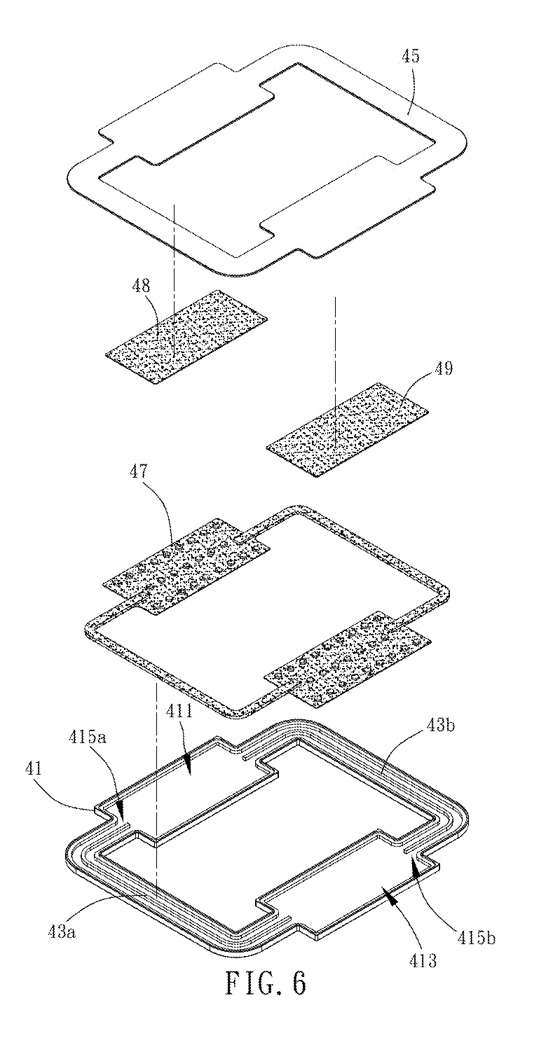

Referring to FIG. 6, an upper lid 45, a base 41, a first capillarity layer 47, a second capillarity layer 48 and a third capillarity layer 49 are formed in the same manner, connected by the same means, and intended to serve the same purposes as their aforesaid counterparts and thus, for the sake of brevity, are not described below. As shown in FIG. 6, two extension grooves 415a, 415b are not only located to the left and right of a first chamber 411 and a second chamber 413, respectively, but also extend outward from the first chamber 411 and then extend linearly before bending to extend to the second chamber 413. Two partition walls 43a, 43b extend in the same direction as the two extension grooves 415a, 415b. Therefore, the ways of extending the extension grooves or the partition walls are not limited by the aforesaid embodiments and are not necessarily the same.

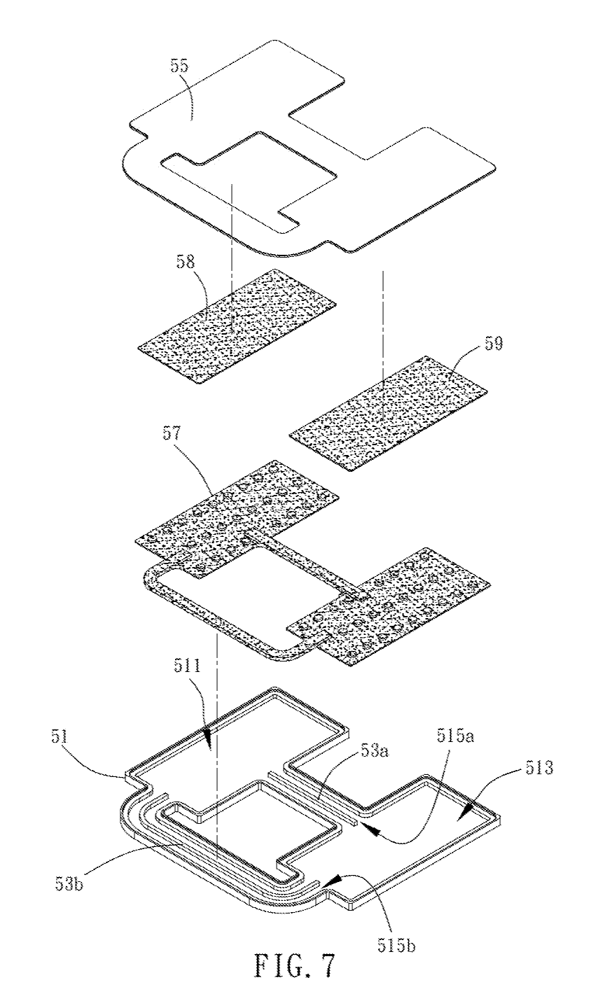

Referring to FIG. 7, an upper lid 55, a base 51, a first capillarity layer 57, a second capillarity layer 58 and a third capillarity layer 59 are formed in the same manner, connected by the same means, and intended to serve the same purposes as their aforesaid counterparts and thus, for the sake of brevity, are not described below. As shown in FIG. 7, an extension groove 515a and an extension groove 515b run parallel to each other substantially. The extension groove 515a extends from a first chamber 511 toward a second chamber 513. The extension groove 515b, which is disposed behind the first chamber 511 and the second chamber 513, extends from the first chamber 511 backward, then laterally and linearly, before extending forward to reach the second chamber 513. Two partition walls 53a, 53b extend in the same direction as the two extension grooves 515a, 515b.

Referring to FIG. 8, an upper lid 65, a base 61, a first capillarity layer 67, a second capillarity layer 68 and a third capillarity layer 69 are formed in the same manner, connected by the same means, and intended to serve the same purposes as their aforesaid counterparts and thus, for the sake of brevity, are not described below. Two extension grooves 615a, 615b extend in the same manner as their counterparts shown in FIG. 6. The embodiment depicted by FIG. 8 is distinguished from the other embodiments of the present disclosure by an extension groove 615c. The extension groove 615c is disposed in front of a first chamber 611 and a second chamber 613 and extends from the first chamber 611 forward and then laterally before bending and extending to reach the second chamber 613.

FIGS. 5-8 show that more airstream channels and capillarity channels are formed as a result of more extension grooves and partition walls, so as to enhance the efficiency of heat transfer.

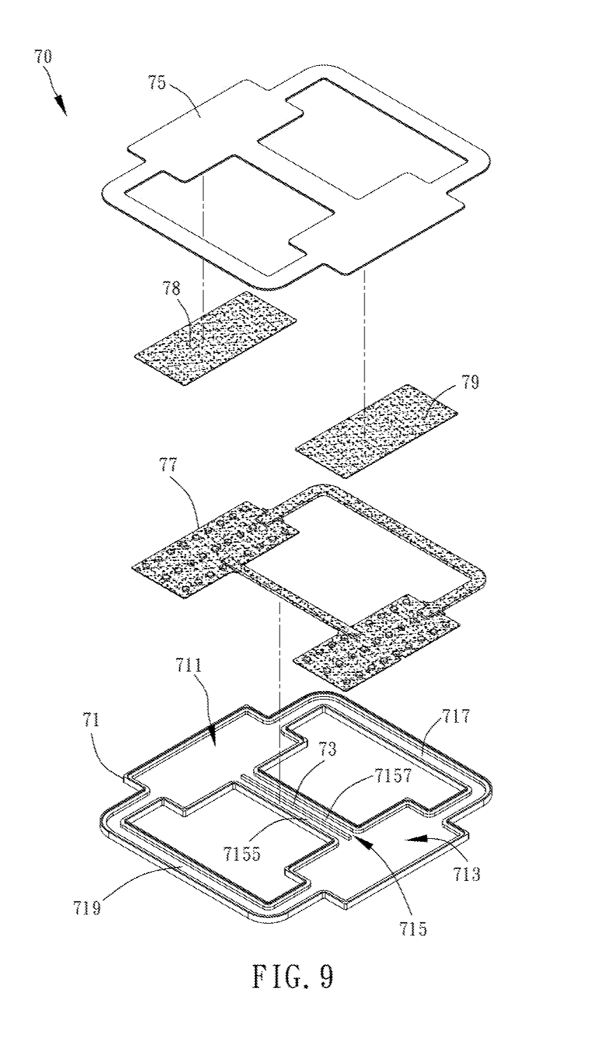

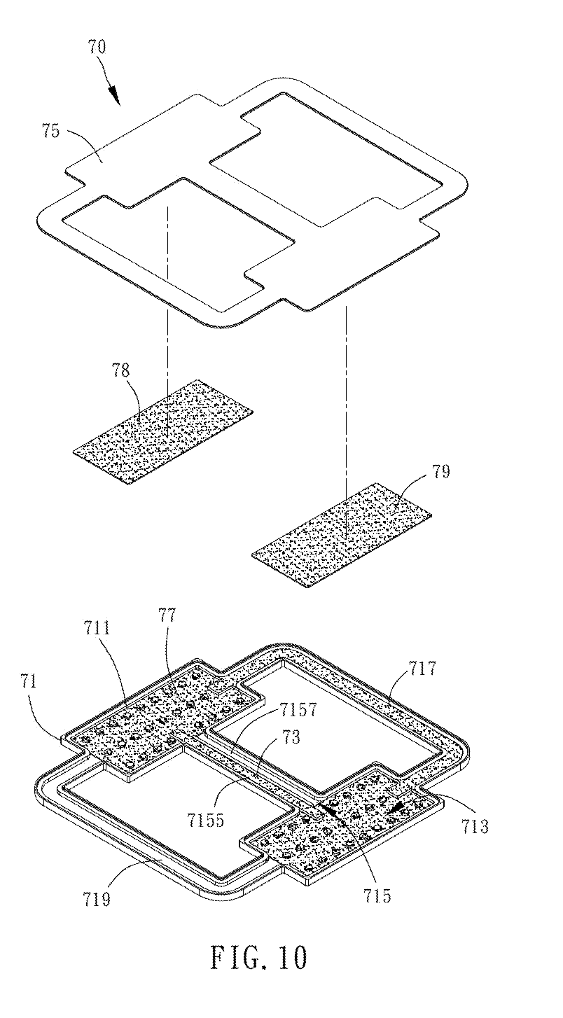

In another embodiment, a base 71 of a loop heat transfer device 70 of the present disclosure has a capillarity groove 717 and a airstream groove 719. As shown in FIGS. 9-10, an upper lid 75, the base 71, a first capillarity layer 77, a second capillarity layer 78 and a third capillarity layer 79 are formed in the same manner, connected by the same means, and intended to serve the same purposes as their aforesaid counterparts and thus, for the sake of brevity, are not described below. The capillarity groove 717 connects to a first chamber 711 and a second chamber 713 communicatively. The airstream groove 719 connects to the first chamber 711 and the second chamber 713 communicatively. In this embodiment, in addition to the first chamber 711, the second chamber 713 and an extension groove 715, the enclosed space comprises the capillarity groove 717 and the airstream groove 719. However, in another embodiment, the enclosed space includes more chambers than are described above and thus is not limited by the aforesaid embodiment.

The first capillarity layer 77 is not only disposed in the first chamber 711, the second chamber 713 and a capillarity channel 7155 but also disposed in the capillarity groove 717 and serves the same function as the capillarity layer in the capillarity channel 7155; hence, the function of the first capillarity layer 77 is, for the sake of brevity, not described below. The function of the airstream groove 719 is the same as that of the airstream channels and thus, for the sake of brevity, is not described below.

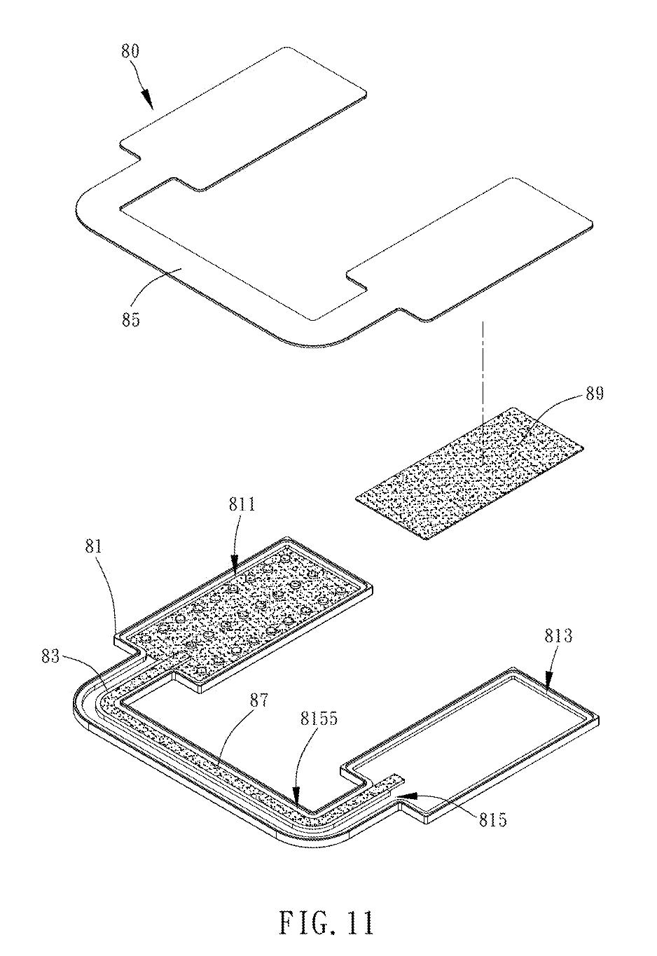

Referring to FIG. 11, the embodiment depicted by FIG. 11 is substantially distinguished from the embodiment depicted by FIG. 2 in that, as shown in FIG. 11, the capillarity structure dispenses with the second capillarity layer 18 of FIG. 2. A loop heat transfer device 80 of the present disclosure comprises a base 81, a partition wall 83, an upper lid 85 and the capillarity structure. The capillarity structure comprises a capillarity layer 87 and another capillarity layer 89 corresponding in position to a second chamber 813. The capillarity layer 87 is connected to the base 81 by sintering. The capillarity layer 87 is disposed in a first chamber 811 and a capillarity channel 8155 and extends to the inside of the second chamber 813 through the capillarity channel 8155. The capillarity layer 87 extendingly disposed inside the second chamber 813 is in contact with another capillarity layer 89 of the upper lid 85 such that the liquid working fluid can still flow through the capillarity layer 87 and the capillarity layer 89, so as to achieve heat transfer and heat dissipation.

The embodiment depicted by FIG. 11 has less layers than the embodiment depicted by FIG. 2 in terms of the capillarity structure. However, the capillarity structure with less layers may also be configured in another manner and thus is not restricted to the embodiment depicted by FIG. 11. The capillarity structure with more layers is capable of dividing each capillarity layer into more layers. In the aforesaid embodiments, the capillarity structure is disposed within the enclosed space and inside a first chamber, a second chamber and a capillarity channel. Specifically speaking, the capillarity structure is entirely or partially disposed inside the chambers and the capillarity channel or upward extension portions of the chambers or the capillarity channel.

Therefore, the loop heat transfer device of the present disclosure comprises a capillarity channel and an airstream channel which are adjacent but fully separated such that a working fluid capable of liquid and gaseous conversion can flow within and between a first chamber and a second chamber efficiently to therefore enhance heat transfer and heat dissipation.

Constituent elements disclosed in the aforesaid embodiments of the present disclosure are illustrative of the present disclosure only, but shall not be interpreted as restrictive of the scope of the present disclosure. Hence, all equivalent elemental replacements or changes made to the aforesaid embodiments shall fall within the scope of the present disclosure. Accordingly, the legal protection for the present disclosure shall be defined by the appended claims.

What is claimed is:

1. A loop heat transfer device, having therein an enclosed space being vacuum and filled with a working fluid, the loop heat transfer device comprising:
a base comprising a first chamber, a second chamber and an extension groove, the extension groove extending from the first chamber to the second chamber, the extension groove having a first end and a second end, the first end corresponding in position to the first chamber, and the second end corresponding in position to the second chamber;
a partition wall connecting to the base and extending from the first end of the extension groove to the second end of the extension groove so as to partition the extension groove into a capillarity channel and an airstream channel, wherein the capillarity channel and the airstream channel communicate to the first chamber and the second chamber;
an upper lid connecting to the base and the partition wall, allowing the enclosed space to contain the first chamber, the second chamber and the extension groove; and
a capillarity structure disposed in the first chamber, the second chamber, and the capillarity channel of the extension groove.

2. The loop heat transfer device of claim 1, wherein the capillarity channel and the airstream channel occupy space of the extension groove space equally.

3. The loop heat transfer device of claim 1, wherein the capillarity channel and the airstream channel occupy space of the extension groove space unequally.

4. The loop heat transfer device of claim 3, wherein the capillarity channel takes up less space than the airstream channel.

5. The loop heat transfer device of claim 3, wherein the capillarity channel takes up more space than the airstream channel.

6. The loop heat transfer device of claim 1, wherein the base further comprises a capillarity groove and an airstream groove such that the capillarity groove and the airstream groove communicate to the first chamber and the second chamber, and the enclosed space further comprises the capillarity groove and the airstream groove, with the capillarity structure disposed in the capillarity groove.

7. The loop heat transfer device of claim 1, wherein the capillarity structure comprises a first capillarity layer, a second capillarity layer and a third capillarity layer, the first capillarity layer is connected to the base by sintering, the second capillarity layer is formed at the upper lid and faces the first chamber, the third capillarity layer is formed at the upper lid and faces the second chamber, allowing a hollow-core cavity to not only be disposed between the first capillarity layer and the second capillarity layer and between the first capillarity layer and the third capillarity layer but also communicate to the airstream channel.

8. The loop heat transfer device of claim 7, wherein the first capillarity layer has a plurality of support portions spaced apart and disposed in the hollow-core cavities to support the base and the upper lid.

9. The loop heat transfer device of claim 1, wherein the upper lid matches the base in profile.

10. The loop heat transfer device of claim 1, wherein the partition wall extends upward from the base to the upper lid.

11. The loop heat transfer device of claim 1, wherein a bottom surface of the first chamber, a bottom surface of the second chamber, and a bottom surface of the extension groove located on a same horizontal plane.
